(19) United States
(12) Patent Application Publication
(10) Pub. No.: US 2024/0321675 A1
(43) Pub. Date: Sep. 26, 2024

(54) SEMICONDUCTOR DEVICE

(71) Applicant: FUJI ELECTRIC CO., LTD., Kawasaki-shi (JP)

(72) Inventor: Satoshi KANEKO, Matsumoto-city (JP)

(73) Assignee: FUJI ELECTRIC CO., LTD., Kawasaki-shi (JP)

(21) Appl. No.: 18/678,778

(22) Filed: May 30, 2024

Related U.S. Application Data
(63) Continuation of application No. PCT/JP2023/017306, filed on May 8, 2023.

(30) Foreign Application Priority Data
Jun. 13, 2022 (JP) 2022-095159

(51) Int. Cl. H01L 23/373; H01L 23/00; H01L 23/047

(52) U.S. Cl. CPC H01L 23/3735; H01L 23/047; H01L 24/32; H01L 24/48; H01L 24/73; H01L 2224/32225; H01L 2224/48225; H01L 2224/73265; H01L 2924/3512

(57) ABSTRACT

A semiconductor device, including: an insulating board; a conductive plate that is provided on the insulating board; and a terminal that is bonded to the conductive plate via a bonding material. The conductive plate has a structure formed in a predetermined region adjacent to an end portion thereof, such that spreading of the bonding material to the end portion is suppressible by the structure.

### CROSS-REFERENCE TO RELATED APPLICATION

This application is a continuation application of International Application PCT/JP2023/017306 filed on May 8, 2023, which designated the U.S., which claims priority to Japanese Patent Application No. 2022-095159, filed on Jun. 13, 2022, the entire contents of which are incorporated herein by reference.

### BACKGROUND OF THE INVENTION

### 1. Field of the Invention

The embodiments discussed herein relate to a semiconductor device in which a terminal is bonded to a substrate using a bonding material.

### 2. Background of the Related Art

Semiconductor devices include power devices, and as one example are used as power converter apparatuses. A power device is a semiconductor chip such as an insulated gate bipolar transistor (IGBT) or a power metal-oxide-semiconductor field-effect transistor (power MOSFET).

Electronic components including semiconductor chips and the like are mounted via solder on a ceramic circuit board. A ceramic circuit board includes an insulating board and a plurality of conductive plates formed on the insulating board. In this type of semiconductor device, terminals of an electronic component, a lead frame, and the like are fixed to the conductive plates by melting and solidifying solder. However, there are cases where molten solder flows out from the bonding regions of terminals, making it important to take measures against solder flowing out in this way.

As one example of a related technology, a technology has been proposed in which a plating film on a circuit board is irradiated with a laser to produce a resist portion, which is an oxide film that repels solder (see Japanese Laid-open Patent Publication No. 2021-118350). A technology for forming a solder dam on the surface of a copper circuit pattern to prevent molten solder from flowing out has also been proposed (see Japanese Laid-open Patent Publication No. 2004-363216). In addition, a technology that forms a protrusion between a soldering region and a wire bonding region on the surface of a copper plate to prevent solder from flowing out has been proposed (see Japanese Laid-open Patent Publication No. 2000-286289).

A technology that forms a thinned portion by molding around a heat diffusion plate to balance the stress that acts on a solder layer has also been proposed (see Japanese Laid-open Patent Publication No. H07-221265). In addition, a technology where a bonding layer protrudes from an end portion of a metal member by 0.1 to 1.0 times the thickness of the metal member to improve heat cycle resistance has also been proposed (Japanese Laid-open Patent Publication No. H10-190176). As yet another example, a technology where a metal plate is bonded to the main surface of a ceramic substrate via a brazing material layer, and the brazing material layer is formed so as to protrude outward from the side surfaces of metal circuit patterns formed on the metal plate has been proposed (Japanese Laid-open Patent Publication No. H11-340598).

When molten solder flows out from the bonding region of a terminal and spreads to an edge of a conductive plate, cracking may occur in the ceramic circuit board when a heat cycle test is performed, for example. This is because the ceramic circuit board is affected by the expansion and contraction of the solder below the terminal, which concentrates stress in the ceramic circuit board around the solder and may cause cracking.

In the past, the occurrence of cracking in a ceramic circuit board has been prevented by curving end portions of the conductive plate in the periphery of the solder where cracking may occur in the ceramic circuit board to alleviate the stress caused by expansion and contraction of the solder.

However, when a mounting layout of semiconductor chips does not have sufficient space in the peripheral part of a ceramic circuit board where cracking may occur, it is difficult to take countermeasures such as curving the end portions of the conductive plate.

FIGS. 15 and 16 depict an example configuration where the end portion of a conductive plate is curved. The ceramic circuit board 100 has an insulating board 110 formed on a metal plate (not depicted), and a conductive plate 120 that is formed on the insulating board 110. Terminals (not illustrated) are bonded to the conductive plate 120 by solder 130a to 130d. The solder 130b and 130d is surrounded by a separation channel m. Component regions 121 to 124 on the conductive plate 120 are regions where semiconductor chips are mounted.

When the solder 130a under a terminal is in a molten state, there is a risk of the solder 130a spreading as far as an end portion eg0 of the conductive plate 120. For this reason, it would be conceivable to take countermeasures such as curving the end portion eg0 of the conductive plate 120 where there is a high risk of cracking occurring in the ceramic circuit board 100.

However, when the distance (or “frame dimension”) from the end portion of the insulating board to the end portion of the conductive plate conforms to an insulation standard and, as depicted in FIG. 15, a curved shape sp1 is provided along the entire edge of the conductive plate 120 including the end portion eg0, the end portion eg0 region is cut away to become smaller. The component regions 121 and 122 on the conductive plate 120 are also partially cut away, making it difficult to mount semiconductor chips in the component regions 121 and 122.

One conceivable solution would be to locally form a curved shape sp2 at the end portion eg0 of the conductive plate 120 as depicted in FIG. 16. FIG. 17A depicts an example configuration before a curved shape is provided at the end portion of the conductive plate, and FIG. 17B depicts an example where a curved shape has been provided. With the structure without the curved shape in FIG. 17A, the solder 130a reaches the end portion eg0 of the conductive plate 120. When the curved shape sp2 is locally provided at the end portion eg0 of the conductive plate 120, the curved shape sp2 provided on the conductive plate 120 will protrude outward like the structure depicted in FIG. 17B. In this case, the frame dimension sz, which is the distance between the end portion of the curved shape sp2 of the conductive plate 120 and the end portion of the insulating board 110, is unable to be maintained, which makes it difficult to conform to the insulation standard.

As described above, the current practice of alleviating the concentration of stress in a ceramic circuit board by curving the edges of a conductive plate may be difficult to implement depending on the mounting layout of semiconductor chips. There is demand for a technology that effectively alleviates the concentration of stress in a ceramic circuit board due to the spreading of solder without depending on the mounting layout of semiconductor chips and thereby prevents the occurrence of cracking in the ceramic circuit board.

### SUMMARY OF THE INVENTION

According to one aspect, there is provided a semiconductor device, including: an insulating board; a conductive plate that is provided on the insulating board; and a terminal that is bonded to the conductive plate via a bonding material, wherein the conductive plate has a structure formed in a predetermined region adjacent to an end portion thereof, such that spreading of the bonding material to the end portion is suppressible by the structure.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 depicts an example configuration of a semiconductor device according to the present disclosure;

FIG. 2 depicts one distance from an end portion of a conductive plate to a solder-adhering region;

FIG. 3 depicts another distance from an end portion of a conductive plate to a solder-adhering region;

FIG. 4 depicts the relationship between stress and a distance from an end portion of a conductive plate to a solder-adhering region;

FIG. 5 depicts example analysis results;

FIG. 6 depicts one example of a solder spreading suppressing structure. FIG. 6 (a) is a plan view, when looking from a front surface side, of a ceramic circuit board where solder below a terminal adheres to a conductive plate, and FIG. 6 (b) is a side view of the ceramic circuit board when looking from a direction A;

FIG. 7 depicts one example of a solder spreading suppressing structure. FIG. 7 (a) is a plan view, when looking from a front surface side, of a ceramic circuit board where solder below a terminal adheres to a conductive plate, and FIG. 7 (b) is a side view of the ceramic circuit board when looking from a direction A;

FIG. 8 depicts one example of a solder spreading suppressing structure. FIG. 8 (a) is a plan view, when looking from a front surface side, of a ceramic circuit board where solder below a terminal adheres to a conductive plate, and FIG. 8 (b) is a side view of the ceramic circuit board when looking from a direction A;

FIG. 9 depicts one example of a solder spreading suppressing structure. FIG. 9 (a) is a plan view, when looking from a front surface side, of a ceramic circuit board where solder below a terminal adheres to a conductive plate, and FIG. 9 (b) is a cross-sectional view of the ceramic circuit board when looking from a direction B;

FIG. 10 depicts example analysis results;

FIG. 11 depicts one example of a solder spreading suppressing structure. FIG. 11 (a) is a plan view, when looking from a front surface side, of a ceramic circuit board where solder below a terminal adheres to a conductive plate, and FIG. 11 (b) is a cross-sectional view of the ceramic circuit board when looking from a direction B;

FIG. 12 depicts example analysis results;

FIG. 13 depicts one example of a solder spreading suppressing structure. FIG. 13 (a) is a plan view, when looking from a front surface side, of a ceramic circuit board where solder below a terminal adheres to a conductive plate, and FIG. 13 (b) is a cross-sectional view of the ceramic circuit board when looking from a direction B;

FIG. 14 depicts example analysis results;

FIG. 15 depicts an example configuration where the end portion of a conductive plate is curved;

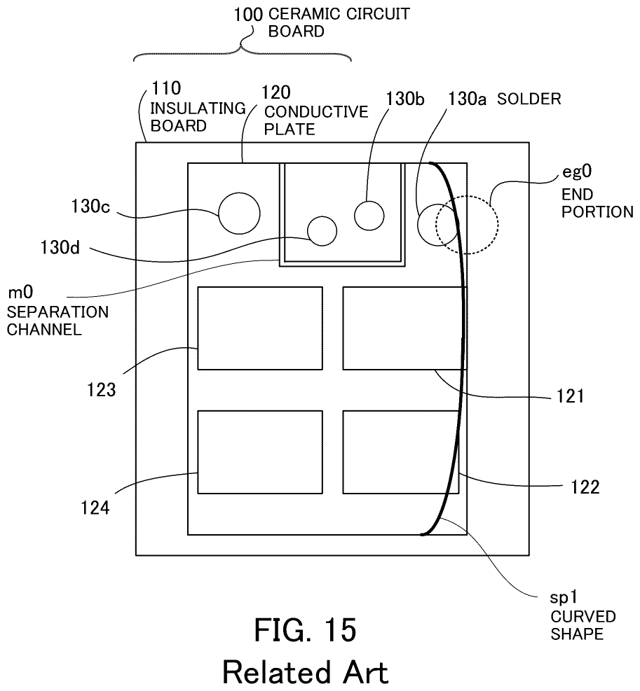

FIG. 16 depicts an example configuration where the end portion of a conductive plate is curved; and

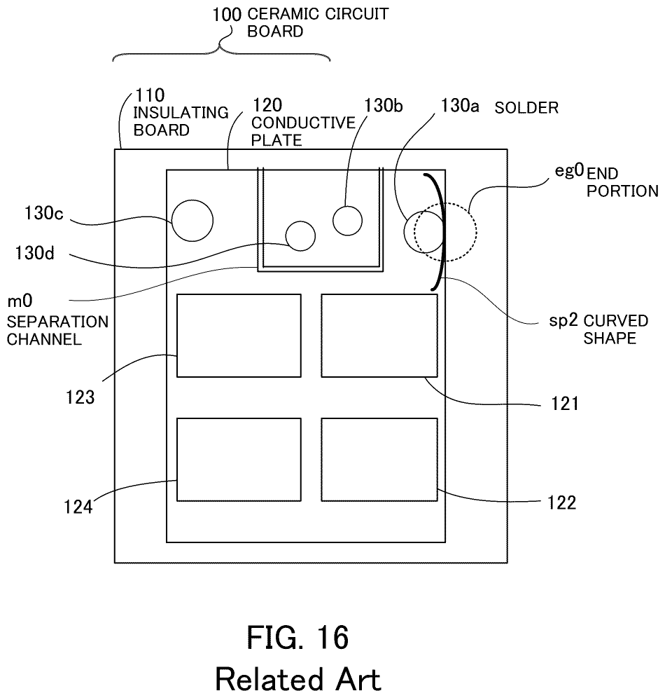

FIGS. 17A and 17B depict one example of before and after provision of a curved shape at an end portion of a conductive plate. FIG. 17A depicts the structure before provision of the curved shape, and FIG. 17B depicts one example structure after provision of the curved shape.

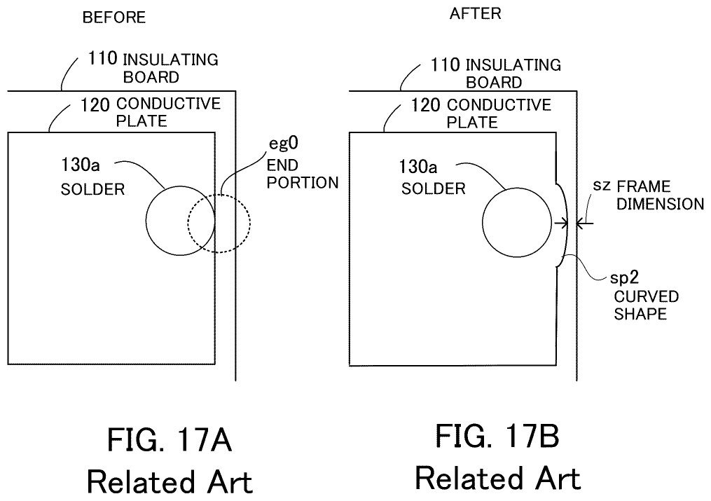

### DETAILED DESCRIPTION OF THE INVENTION

Several embodiments will be described below with reference to the accompanying drawings. Note that in the drawings and the following description, elements with configurations that are effectively the same have been assigned the same reference d duplicated description may be omitted. In the following description, the expression “upper surface” refers to a surface that faces upward when the drawings are upright. In the same way, the expressions “up” and “upper part” refer to an upward direction when the drawings are upright. The expression “below” refers to the downward direction when the drawings are upright. These expressions relating to directions have the same meaning for all of the drawings. The expressions “upper surface”, up”, “upper part”, and “below” are merely convenient expressions used to specify relative positional relationships, and are not intended to limit the technical scope of the present disclosure.

### Configuration of Semiconductor Device

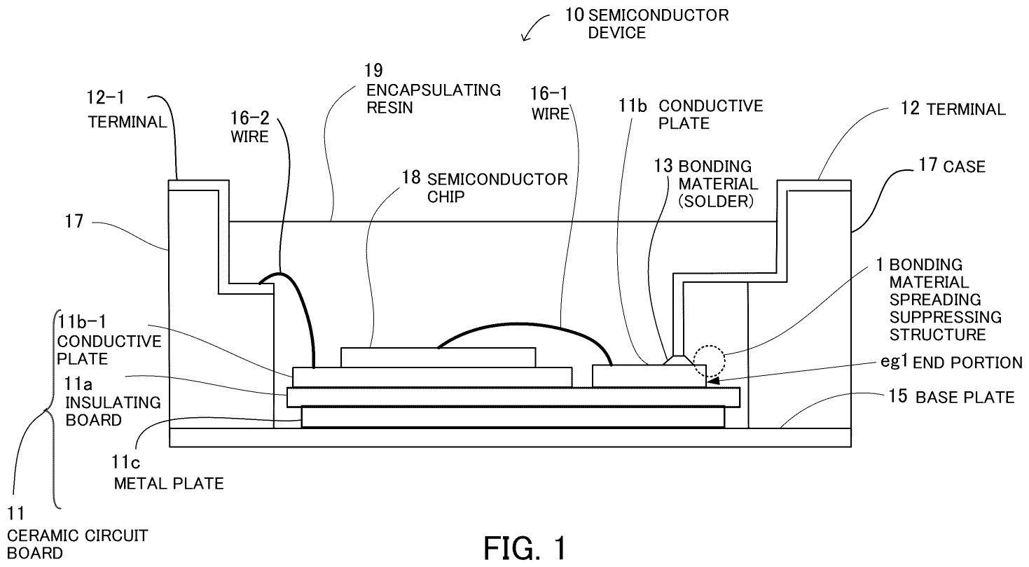

FIG. 1 depicts an example configuration of a semiconductor device according to the present disclosure. A semiconductor device 10 is depicted in a cross-sectional view. The semiconductor device 10 includes a ceramic circuit board 11, and terminals 12 and 12-1 and a semiconductor chip 18 connected to a front surface of the ceramic circuit board 11.

The ceramic circuit board 11 includes an insulating board 11a, conductive plates 11b and 11b-1, and a metal plate 11c. When, as one example, the conductive plates 11b and 11b-1 and the metal plate 11c are copper foil patterns, it is possible to use a direct copper bonding (DCB) substrate where the conductive plates 11b and 11b-1 and the metal plate 11c are directly bonded to both sides of the insulating board 11a.

The ceramic circuit board 11 is mounted on the surface of a base plate 15, and the terminal 12 provided on a case 17 is bonded via a bonding material 13 to the conductive plate 11b of the ceramic circuit board 11.

A bonding material spreading suppressing structure 1, which suppresses spreading of the solder 13 that has melted and is described in detail later, is provided near an end portion eg1 of the conductive plate 11b. Note that although solder, a brazing material, or the like may be used as the bonding material 13, the bonding material is referred to as “solder” in the following description.

The semiconductor chip 18 is bonded to the conductive plate 11b-1 via solder. A wire 16-1 connects an electrode of the semiconductor chip 18 and the conductive plate 11b, which is a lead electrode of the ceramic circuit board 11. A wire 16-2 connects the conductive plate 11b-1 and the terminal 12-1 provided on the case 17. Wire bonding using ultrasound and a load is performed to bond the wires 16-1 and 16-2.

The wires 16-1 and 16-2 are made of a conductive metal, such as copper or aluminum, or a conductive alloy, such as an iron-aluminum alloy, and are formed with a diameter of 300 to 500 μm for a high voltage device, for example.

The ceramic circuit board 11 to which the semiconductor chip 18 has been bonded is housed in the case 17, and a region surrounded by the case 17 and the base plate 15 is filled with encapsulating resin 19 to encapsulate the semiconductor device. Note that the case 17 and the base plate 15 are attached using adhesive or the like.

As one example, the insulating board 11a of the ceramic circuit board 11 is an electrically insulating ceramic, such as aluminum nitride, silicon nitride, or aluminum oxide, and is a plate-shaped member with a thickness of 0.2 to 1 mm, for example.

The conductive plates 11b and 11b-1 of the ceramic circuit board 11 are provided on the upper surface of the insulating board 11a and are made of a material with superior electrical conductivity. As examples, this material is copper, aluminum, or an alloy containing at least one of these materials. The thickness of the conductive plates 11b and 11b-1 is 0.2 mm, for example.

In addition to the semiconductor chip 18, wiring members, such as bonding wires, a lead frame, and connection terminals, and electronic components may be disposed as appropriate and as needed on the conductive plates 11b and 11b-1.

Note that the number, disposed positions, and shapes of the conductive plates 11b and 11b-1 may be selected as appropriate for the semiconductor device design. The metal plate 11c of the ceramic circuit board 11 is made of an electrically conductive metal, such as copper or aluminum, has a thickness of 0.1 to 1 mm, for example, and is provided on the lower surface of the insulating board 11a.

As the base plate 15, a copper substrate, an aluminum silicon carbide composite material (Al—SiC) substrate, or the like with high heat dissipation performance may be used. The semiconductor chip 18 is a power device made of silicon, silicon carbide, or gallium nitride. The semiconductor chip 18 includes a switching element. Switching elements include power MOSFETs, IGBTs, and the like.

As examples, this semiconductor chip 18 includes a drain electrode (or positive electrode, in an IGBT, the “collector electrode”) and a source electrode (or negative electrode, in an IGBT, the “emitter electrode”) as main electrodes, and a gate electrode as a control electrode.

The semiconductor chip 18 also includes a diode element. As examples, the diode element is a freewheeling diode (FWD) where a Schottky barrier diode (SBD), a P-intrinsic-N (PiN) diode, or the like is connected in inverse-parallel to a switching element.

Note that other electronic components may be disposed as needed on the conductive plates 11b and 11b-1. As examples, such electronic components may be a capacitor, a resistor, a thermistor, a current sensor, and a control integrated circuit. The solder 13 is resistant to voiding and has high temperature resistance. As one example, the solder 13 is an alloy whose main components are tin and antimony. Note that a gel filler may be used as the encapsulating resin 19.

Relationship Between Stress and Distance from End Portion of Conductive Plate to Solder-Adhering Region

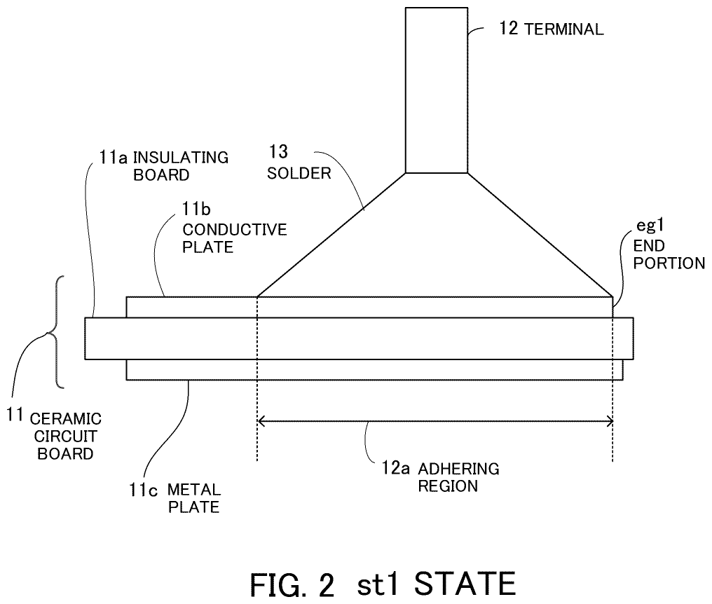

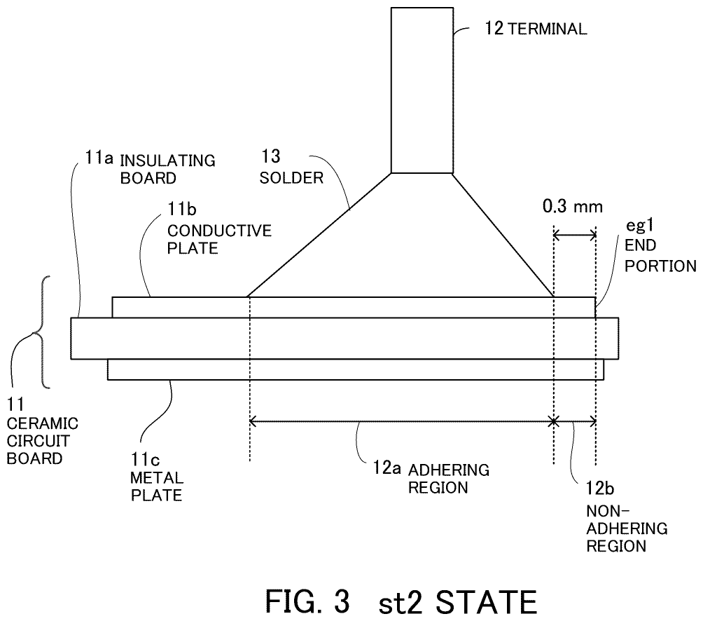

Next, the relationship between stress and the distance from an end portion of the conductive plate to a solder-adhering region will be described using FIG. 2 to FIG. 5. FIG. 2 and FIG. 3 depict different distances from the end portion of the conductive plate to the solder-adhering region. In states st1 and st2 depicted in FIG. 2 and FIG. 3 respectively, the terminal 12 is bonded to the conductive plate 11b via the solder 13.

[State st1] The distance from the end portion eg1 of the conductive plate 11b to an adhering region 12a of the solder 13 is 0 mm. That is, the solder 13 spreads out to reach the end portion eg1 of the conductive plate 11b, resulting in the solder 13 adhering to the end portion eg1 of the conductive plate 11b.

[State st2] The distance from the end portion eg1 of the conductive plate 11b to the adhering region 12a of the solder 13 is 0.3 mm. That is, the solder 13 does not spread as far as the end portion eg1 of the conductive plate 11b, and a non-adhering region 12b with no adhering solder 13 exists in a 0.3 mm-wide section from the end portion eg1 to the adhering region 12a of the solder 13.

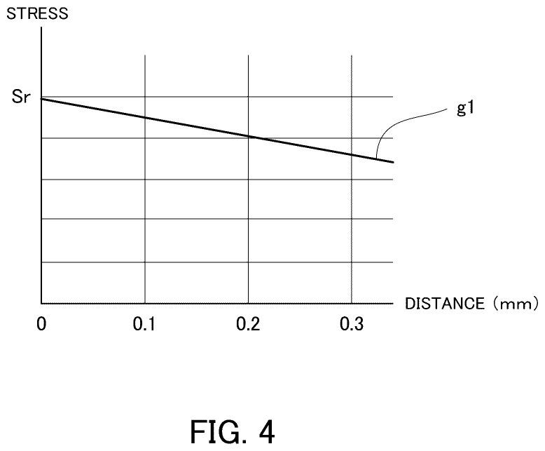

FIG. 4 depicts the relationship between the stress and the distance from the end portion of the conductive plate to the solder-adhering region. The vertical axis represents the stress that acts on the ceramic circuit board 11 and the horizontal axis represents the distance (in mm) from the end portion eg1 of the conductive plate 11b to the adhering region 12a of the solder 13.

The line g1 in FIG. 4 indicates the analysis results. As the distance from the end portion eg1 of the conductive plate 11b to the adhering region 12a of the solder 13 increases, stress falls, which means that the risk of the ceramic circuit board 11 cracking also falls.

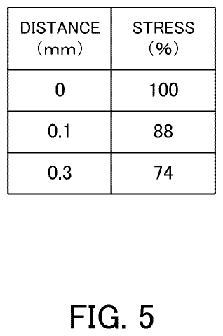

FIG. 5 depicts example analysis results. FIG. 5 is a table of analysis results, and indicates distances (in mm) from the end portion eg1 of the conductive plate 11b to the adhering region 12a of the solder 13, and stress produced in the ceramic circuit board 11 expressed as a relative value, which is a percentage of the stress when the distance is zero.

In FIG. 5, corresponding values of distance (in mm) and stress as a percentage are [0, 100], [0.1, 88], and [0.3, 74]. These values demonstrate that the stress produced in the ceramic circuit board 11 tends to fall as the distance from the end portion eg1 of the conductive plate 11b to the adhering region 12a of the solder 13 increases. Accordingly, as one example, by ensuring that the distance is around 0.3 mm as indicated in FIG. 3, compared to the case where the distance from the end portion eg1 of the conductive plate 11b to the adhering region of the solder 13 is 0 mm, the stress falls by approximately 26%, which increases the resistance to cracking of the ceramic circuit board 11.

### Solder Spreading Suppressing Structure #1

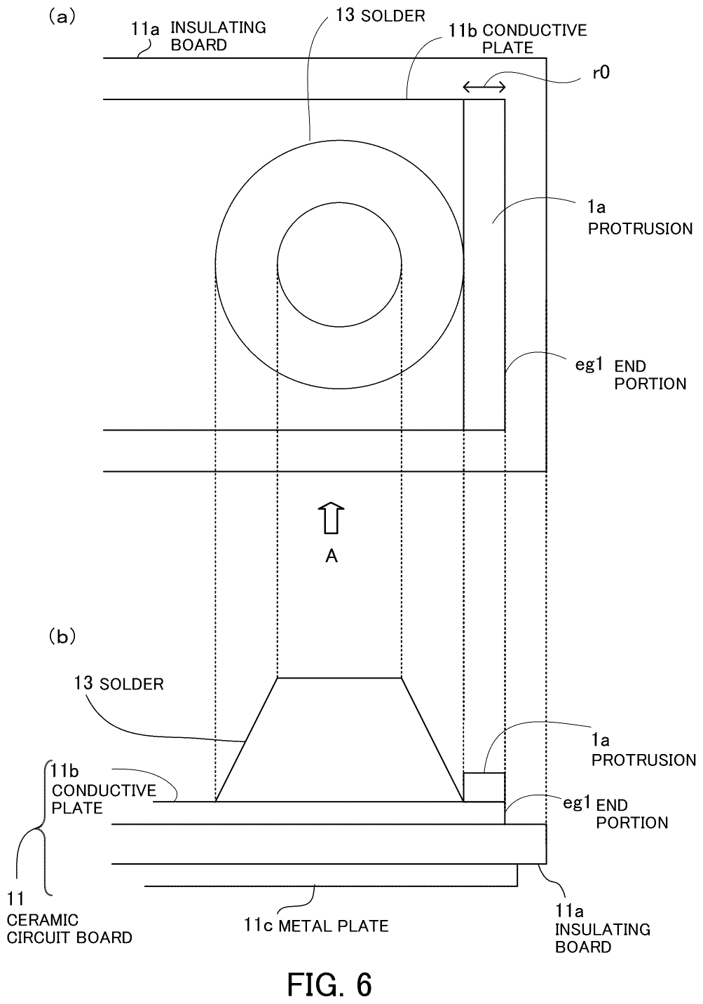

Next, a structure for suppressing the spreading of the solder 13 to the end portion eg1 of the conductive plate 11b will be described with reference to FIG. 6 to FIG. 8. FIG. 6 depicts one example of a solder spreading suppressing structure. FIG. 6 (a) is a plan view, when looking from a front surface side, of a ceramic circuit board where solder below a terminal adheres to a conductive plate, and FIG. 6 (b) is a side view of the ceramic circuit board when looking from a direction A.

A protrusion (e.g., convex) 1a is provided in a predetermined region r0 of the conductive plate 11b, which is near the end portion eg1 thereof where adhesion of the solder 13 is undesirable, thereby producing a protrusion structure. As one example, the protrusion 1a is made of a resin that has high heat resistance so that peeling and deterioration do not occur at the heating temperature used during soldering. As one example, thermosetting resin may be used. Examples of thermosetting resin include epoxy resin, phenol resin, maleimide resin, polyester resin, polyimide resin, silicone resin, and polyamide resin.

Alternatively, the protrusion 1a is a metal wire. It is also possible to form a dam wire by bonding a metal wire to the predetermined region r0 near the end portion eg1 of the conductive plate 11b. Example materials of the metal wire include gold, silver, copper, aluminum, and an alloy containing at least one of these metals. The bonding to the conductive plate 11b may be performed by ultrasonic bonding for example.

In this way, by providing the protrusion 1a in the predetermined region r0 of the conductive plat 11b near the end portion eg1 thereof where adhesion of the solder 13 is undesirable, it is possible to suppress the spreading of the solder 13 to the end portion eg1 of the conductive plate 11b and prevent the occurrence of cracking in the ceramic circuit board.

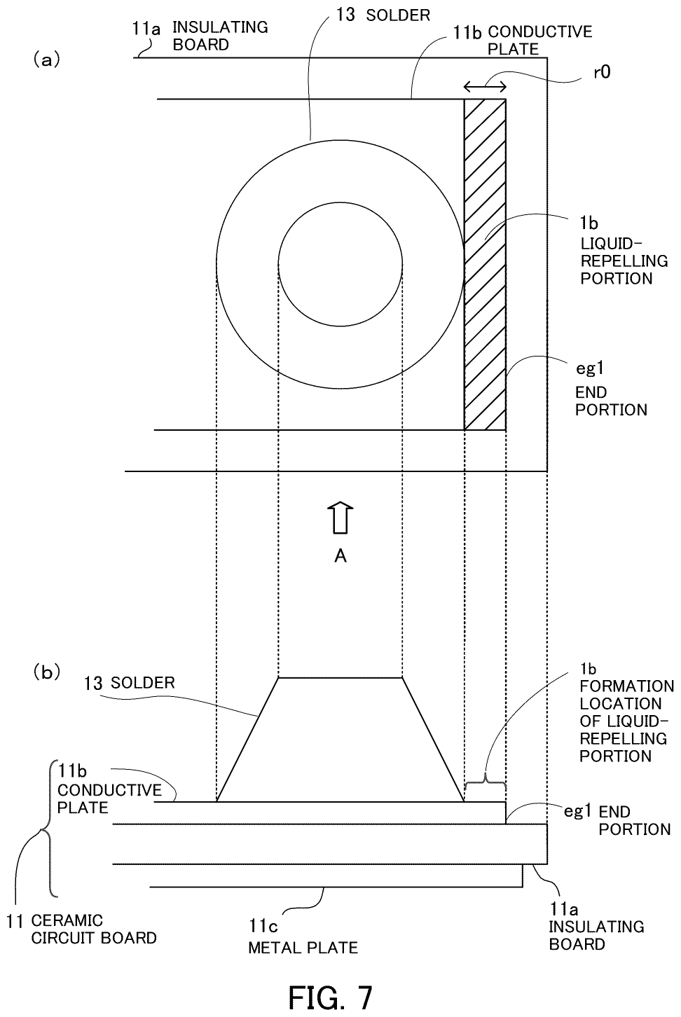

FIG. 7 depicts one example of a solder spreading suppressing structure. FIG. 7 (a) is a plan view, when looking from a front surface side, of a ceramic circuit board where solder below a terminal adheres to a conductive plate, and FIG. 7 (b) is a side view of the ceramic circuit board when looking from a direction A.

A liquid-repelling portion (or “resist”) 1b is provided in a predetermined region r0 of the conductive plate 11b near the end portion eg1 thereof where adhesion of the solder 13 is undesirable. The liquid-repelling portion 1b is an oxide film formed by oxidizing the conductive plate 11b.

As one example, the oxide film is a nickel oxide film. This oxide film is formed by oxidizing a plating film on the conductive plate 11b by irradiating the plating film with a laser. Note that the irradiation with a laser may be performed using either a CW laser that continuously emits laser light or a pulsed laser that intermittently emits laser light.

In this way, by providing the liquid-repelling portion 1b in the predetermined region r0 of the conductive plate 11b near the end portion eg1 thereof where adhesion of the solder 13 is undesirable, it is possible to suppress the spreading of the solder 13 to the end portion eg1 of the conductive plate 11b and prevent the occurrence of cracking in the ceramic circuit board.

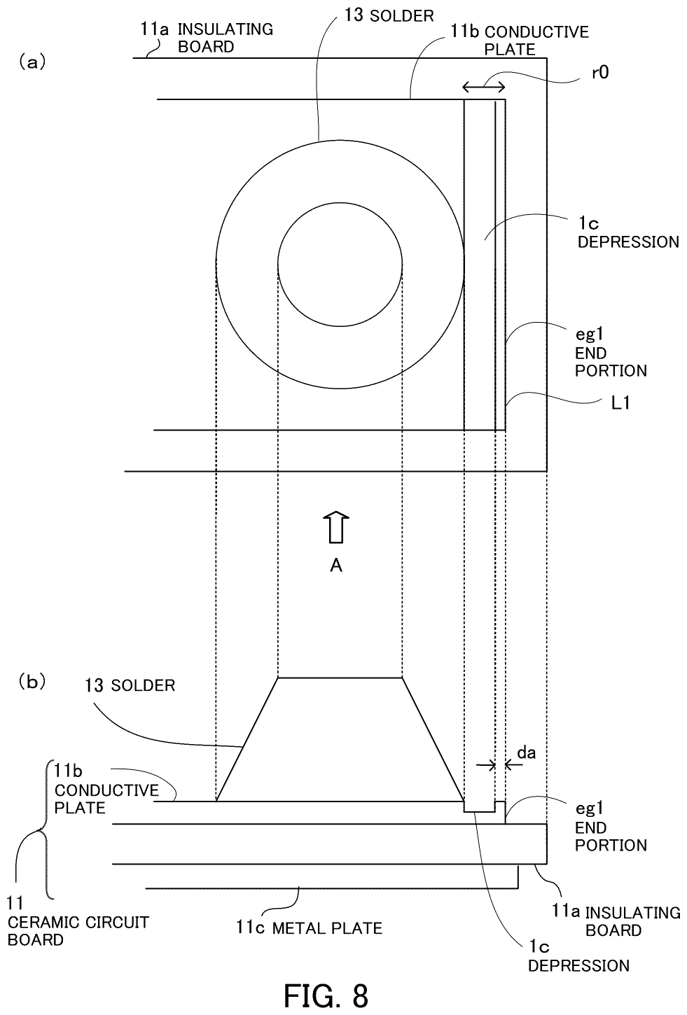

FIG. 8 depicts one example of a solder spreading suppressing structure. FIG. 8 (a) is a plan view, when looking from a front surface side, of a ceramic circuit board where solder below a terminal adheres to a conductive plate, and FIG. 8 (b) is a side view of the ceramic circuit board when looking from a direction A.

A depression (e.g., concave) 1c is provided in a predetermined region r0 of the conductive plate 11b, which is near the end portion eg1 thereof where adhesion of the solder 13 is undesirable, thereby producing a depression structure. The depression 1c is provided at a position a predetermined distance da from the end portion eg1 of the conductive plate 11b. As one example, the depression 1c is a slot provided along the side L1 of the end portion eg1 of the conductive plate 11b.

In this way, by providing the depression 1c in the predetermined region r0 of the conductive plate 11b near the end portion eg1 thereof where adhesion of the solder 13 is undesirable, it is possible to suppress the spreading of the solder 13 to the end portion eg1 of the conductive plate 11b and prevent the occurrence of cracking in the ceramic circuit board.

### Solder Spreading Suppressing Structure #2

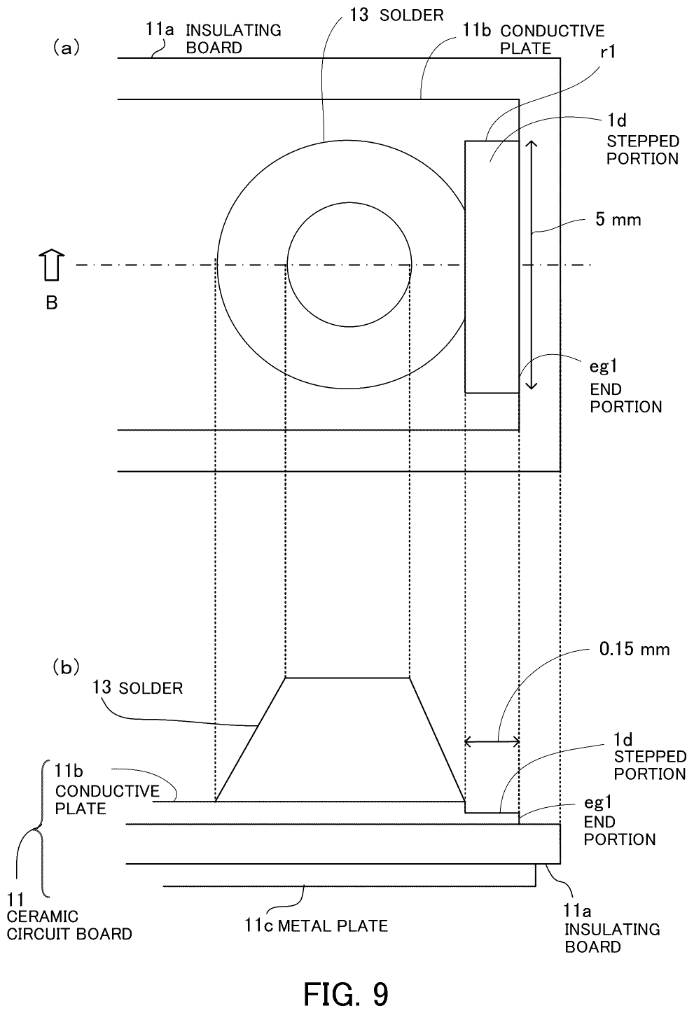

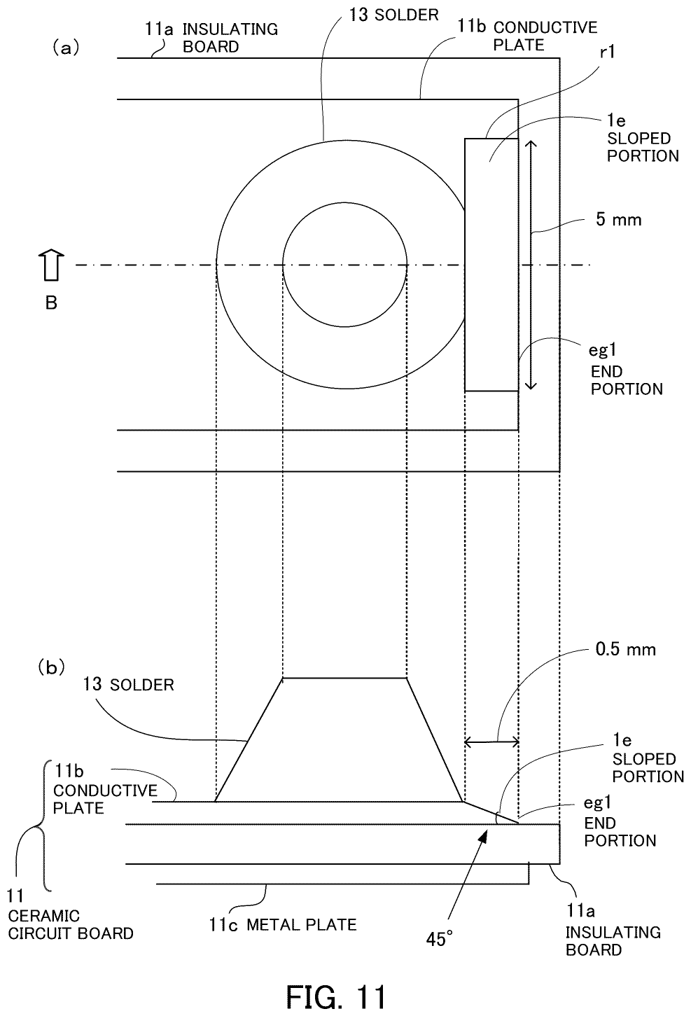

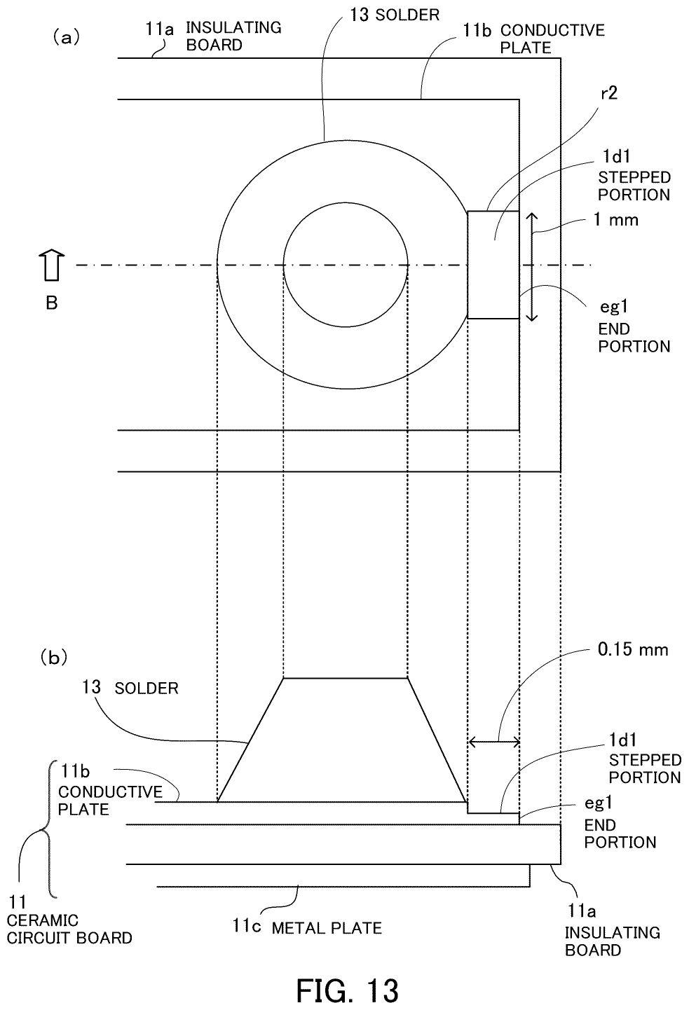

Next, a structure for suppressing the spreading of the solder 13 to the end portion eg1 of the conductive plate 11b will be described using FIGS. 9 to 14. Note that the solder spreading suppressing structure depicted in FIG. 9, FIG. 11, and FIG. 13 has a structure where a reduced thickness portion of the conductive plate 11b is provided at the end portion eg1 of the conductive plate 11b.

FIG. 9 depicts one example of a solder spreading suppressing structure. FIG. 9 (a) is a plan view, when looking from a front surface side, of a ceramic circuit board where solder below a terminal adheres to the conductive plate, and FIG. 9 (b) is a cross-sectional view of the ceramic circuit board when looking from a direction B.

In a predetermined region r1 of the conductive plate 11b near the end portion eg1 thereof where adhesion of the solder 13 is undesirable, a stepped portion 1d is provided to form a reduced thickness portion in the conductive plate 11b. In the example in FIG. 9, the stepped portion 1d with a width of 0.15 mm is formed with a length of 5 mm along the end portion eg1 of the conductive plate 11b.

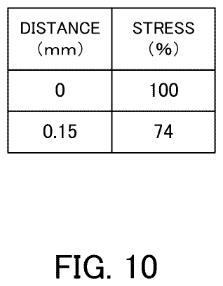

FIG. 10 depicts example analysis results. FIG. 10 is a table of analysis results for the solder spreading suppressing structure in FIG. 9, and indicates distances (in mm) from the end portion eg1 of the conductive plate 11b to the adhering region of the solder 13, and stress that is produced in the ceramic circuit board 11 expressed as a relative value, which is a percentage of the stress when the distance is zero.

In FIG. 10, corresponding values of distance (in mm) and stress as a percentage are [0, 100] and [0.15, 74]. In this way, the stepped portion 1d is provided in the predetermined region r1 of the conductive plate 11b near the end portion eg1 thereof where adhesion of the solder 13 is undesirable, and the distance to the adhering region of the solder 13 is kept at around 0.15 mm.

By doing so, compared to the case where the distance from the end portion eg1 of the conductive plate 11b to the adhering region of the solder 13 is 0 mm, the stress is reduced by approximately 26%, which increases the resistance to cracking of the ceramic circuit board 11. Note that since this structure not only prevents solder from adhering to the ends of the conductive plate but also reduces stress by making the conductive plate thinner, stress is reduced compared to structures where the distance from the end portion of the conductive plate to the solder adhering region is progressively increased as indicated in FIG. 4. FIG. 11 depicts one example of a solder spreading suppressing structure. FIG. 11 (a) is a plan view, when looking from a front surface side, of a ceramic circuit board where solder below a terminal adheres to a conductive plate, and FIG. 11 (b) is a cross-sectional view of the ceramic circuit board when looking from a direction B.

In a predetermined region r1 of the conductive plate 11b near the end portion eg1 thereof where adhesion of the solder 13 to is undesirable, a sloped portion 1e is provided to form a reduced thickness portion in the conductive plate 11b. In the example in FIG. 11, the sloped portion 1e with an angle of 45° is formed with a length of 5 mm along the end portion eg1 of the conductive plate 11b.

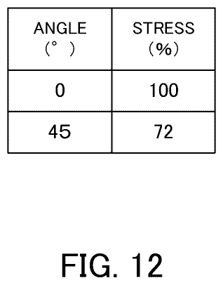

FIG. 12 depicts example analysis results. FIG. 12 is a table of analysis results for the solder spreading suppressing structure in FIG. 11, and indicates the angle (in °) of the sloped portion 1e and stress that is produced in the ceramic circuit board 11 expressed as a relative value, which is a percentage of the stress when the angle is zero.

In FIG. 12, corresponding values of angle (in °) and stress as a percentage are [0, 100] and [45, 72]. In this way, by providing the sloped portion 1e in the predetermined region r1 of the conductive plate 11b near the end portion eg1 thereof where adhesion of the solder 13 is undesirable, compared to when the slope is 0°, the stress falls by around 28%, thereby ensuring that the ceramic circuit board 11 is resistant to cracking. Note that since this structure prevents solder from adhering at an end portion of the conductive plate and also reduces stress by making the conductive plate thinner, in the same way as the structure in FIGS. 9 and 10, stress is reduced compared to structures where the distance from the end portion of the conductive plate to the solder adhering region is progressively increased as indicated in FIG. 4.

FIG. 13 depicts one example of a solder spreading suppressing structure. FIG. 13 (a) is a plan view, when looking from a front surface side, of a ceramic circuit board where solder below a terminal adheres to a conductive plate, and FIG. 13 (b) is a cross-sectional view of the ceramic circuit board when looking from a direction B.

In a predetermined region r2 of the conductive plate 11b near the end portion eg1 thereof where adhesion of the solder 13 is undesirable, a stepped portion 1d1 is locally provided to form a reduced thickness portion in the conductive plate 11b. In the example in FIG. 13, the stepped portion 1d1 with a width of 0.15 mm is formed with a length of 1 mm along the end portion eg1 of the conductive plate 11b.

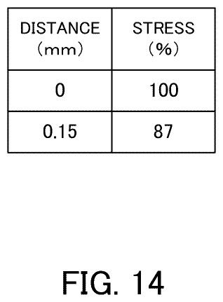

FIG. 14 depicts example analysis results. FIG. 14 is a table of analysis results for the solder spreading suppressing structure in FIG. 13, and indicates distances (in mm) from the end portion of the conductive plate to the adhering region of the solder 13, and stress that is produced in the ceramic circuit board expressed as a relative value, which is a percentage of the stress when the distance is zero.

In FIG. 14, corresponding values of distance (in mm) and stress as a percentage are [0, 100] and [0.15, 87]. In this way, the stepped portion 1d1 is provided in the predetermined region r2 of the conductive plate 11b near the end portion eg1 thereof where adhesion of the solder 13 is undesirable, and the distance to the adhering region of the solder 13 is maintained at around 0.15 mm.

By doing so, compared to the case where the distance from the end portion eg1 of the conductive plate 11b to the adhering region of the solder 13 is 0 mm, stress is reduced by approximately 13%. Although the margin falls slightly compared to the configuration depicted in FIG. 9, it is still possible to prevent cracking of the ceramic circuit board 11 by locally providing the stepped portion 1d1 as depicted in FIG. 13.

Although several embodiments have been described above, the configuration of each part indicated in the embodiments may be replaced with other parts with similar functions. It is also possible to add other freely chosen components or processes. Any two or more configurations (or features) in the embodiments described above may also be combined into single elements.

According to an aspect of the present disclosure, it is possible to alleviate the concentration of stress in a ceramic circuit board and prevent cracking of the ceramic circuit board.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulating board;
a conductive plate that is provided on the insulating board; and
a terminal that is bonded to the conductive plate via a bonding material, wherein
the conductive plate has a structure formed in a predetermined region adjacent to an end portion thereof, such that spreading of the bonding material to the end portion is suppressible by the structure.

2. The semiconductor device according to claim 1, wherein the structure is a protrusion.

3. The semiconductor device according to claim 2, wherein the structure is made of resin.

4. The semiconductor device according to claim 2, wherein the structure is a metal wire bonded to the conductive plate.

5. The semiconductor device according to claim 1, wherein the structure is a liquid-repelling portion produced by oxidizing the predetermined region.

6. The semiconductor device according to claim 5, wherein the liquid-repelling portion is an oxide film produced by irradiating the predetermined region with a laser.

7. The semiconductor device according to claim 1, wherein the structure is a depression, and is provided at a position a predetermined distance from the end portion of the conductive plate.

8. The semiconductor device according to claim 7, wherein the structure is a slot provided along an edge of the end portion of the conductive plate.

9. A semiconductor device, comprising:
an insulating board;
a conductive plate that is provided on the insulating board; and
a terminal that is bonded to the conductive plate via a bonding material, wherein
the conductive plate has a structure formed at an end portion thereof, the structure being so configured that the bonding material adheres to the conductive plate up to a boundary of the structure and does not adhere to the structure, the structure having a reduced thickness.

10. The semiconductor device according to claim 9,
wherein the structure is provided in a predetermined region of the conductive plate to form a step at the end portion.

11. The semiconductor device according to claim 9,
wherein the structure is provided in a predetermined region of the conductive plate to form a slope at the end portion.
